(19) United States
(12) Patent Application Publication
(10) Pub. No.: US 2005/0241570 A1
(43) Pub. Date: Nov. 3, 2005

(54) Crucible and method for growing large crystals, in particular CaF2 monocrystals

(76) Inventors: Kherreddine Lebbou, Villeurbanne (FR); Christian Pedrini, Villeurbanne (FR); Olivier Tillement, Fontaines Saint Martin (FR)

Correspondence Address: CLARK & BRODY, 1090 VERMONT AVENUE, NW, SUITE 250, WASHINGTON, DC, 20005, US

(21) Appl. No.: 11/109,650

(22) Filed: Apr. 20, 2005

Related U.S. Application Data
(60) Provisional application No. 60/618,981, filed on Oct. 18, 2004.

(30) Foreign Application Priority Data
Apr. 22, 2004 (FR) 04 04 276

(51) Int. Cl. C30B 21/02

(52) U.S. Cl. 117/81; 117/223

(57) ABSTRACT

The invention relates to a crucible (I) adapted for growing a large crystal, starting with an adequate raw material, comprising a receptacle (1) intended to accommodate the large crystal, wherein moreover, directly beneath the receptacle (1) a vertical succession of at least two containers (3₁, 3₂, 3₃, 3ₙ) is located, with each container being connected by a restriction zone (41, 42, 43, 4n) to the successive container located directly above, and with the upper container (3₃, 3ₙ) being connected by a restriction zone (4₃, 4ₙ) to the receptacle (1), as well as a growth method that implements said crucible.

The present invention relates to the technical field of methods of growing crystals. More precisely, the object of the invention is a method to control crystallization by favoring axes of low Gibbs energy, as well as a crucible of a form adapted for the implementation of said production method. The present invention is implemented advantageously for growing a CaF₂ monocrystal oriented along the favored growth axis (111).

Several crystal growth methods exist: notably, the crystal growth methods that use conventional pulling techniques, termed Bridgman-Stockbarger, can be cited (Stockbarger “Artificial Fluorite” J. Opt. Soc. Am, vol 39 No. 9 (September 1949) 731-740) and Czochralski (J. M. Ko, S. Tozawa, A. Yoshikawa, K. Inaba, T. Shishido, T. Oba, Y. Oyama, T. Kuwabara, T. Fukuda (J. Crystal Growth 222(2001) 243-248)). The principle of the Bridgman technique is based on the insertion of a crucible filled with raw material into a furnace, which is preferably vertical. In the case of the so-called “vertical” process, the raw material, most often in the form of a polycrystalline powder, is heated above its melting temperature (superheating) so that it will then crystallize (solidification), continuously, by pulling from the bottom of the furnace up to the top. In the case of crystal growth using the Bridgman technique, three pulling configurations are possible: by moving the furnace from the bottom to the top, with the crucible remaining stationary; by moving the crucible from the top to the bottom, with the furnace remaining stationary; or by changing the temperature distribution inside the furnace, with both the furnace and the crucible remaining stationary. The crystalline growth of a monocrystal begins in a specific direction, starting with an external seed cut from a monocrystal that is oriented in the desired direction. By external seed, it is meant a seed present in monocrystal state before the crystallization process begins and not a seed formed in situ during the crystallization process. On one hand, the use of an external seed makes it possible to facilitate the control of the nucleation of a single crystal, and on the other hand to obtain monocrystals that are oriented following the orientation of the seed. FIG. 1 illustrates the principle of crystalline growth using the Bridgman technique. An oriented seed A is placed below the opening of a crucible C in which the raw material B is placed. The crucible C is placed in a vertical furnace D and the raw material is heated to a temperature sufficient to cause it to melt. An insulating barrier E is used in order to separate the heating zone, in which the material is in a melted state, from the cooling zone, in which the material is in a crystalline state.

Monocrystals are formed on crystal seeds when the melt arrives in the section of the furnace where the temperature is lower than the melting point of the material to be crystallized. The quality of the crystal obtained depends on the geometry of the crystallization front at the solid/liquid interface. The crystallization front propagates at the pulling rate through the material placed inside the crucible. When pulling is performed by moving the crucible, the pulling rate corresponds to the rate of travel of the crucible inside the furnace, which is generally between 0.1 and 3 mm/h.

Control of temperature variation inside the pulling furnace, particularly in the region of the molten zone and at the crystallization front, is essential in crystal pulling methods according to the Bridgman technique in which direction is imposed by the orientation of the seed. The thermal cycle is also a determining factor for pulling. Temperature choices in the molten zone and in the seed region are particularly important.

Generally, in the case of CaF₂ crystalline growth by the Bridgman technique for ultraviolet applications, the seed is oriented in the (111) direction, a direction which makes it possible to generate better optical properties and, in particular, transmission greater than 99% and birefringence lower than 0.01 nm/cm. Moreover, cutting in the (111) direction is facilitated since CaF₂ crystals cleave according to the (111) planes.

The growing of fluorides is carried out in graphite crucibles in order to obtain very clean, oxygen-free products. In the case of the crystalline growth of fluorinated materials, the materials are thus pulled under a high vacuum or under an inert atmosphere, in order to avoid problems of oxidation. The presence of oxygen is harmful to, and it degrades the optical properties of, fluorinated crystals. A variety of techniques can be used to absorb the oxygen that exists in the liquid bath. In particular, oxygen scavengers (sacrificial reagents) that are able to absorb oxygen, such as the metal fluorides PbF₂ or ZnF₂, can be used. Their mechanism of action is illustrated below using the example of CaF₂. The scavengers react with the oxide in the liquid (CaO) to form an oxide (PbO, ZnO) that will be easily reduced by graphite to a metal (Pb, Zn), according to the following reactions:
CaO+PbF₂→CaF₂+PbO
CaO+ZnF₂→CaF₂+ZnO

The elimination of oxygen depends, in particular, on the synthesis process and the type of scavenger.

Unfortunately, in the majority of cases, the growth techniques of the prior art are rather expensive due to the enormous production losses that result from the melting of the seed during the pulling process. The melting of the seed causes a loss of crystal orientation with the crystallization of a polycrystalline material. This melting causes a temperature distribution profile change in the crystallization zone that in turn causes a temperature profile change at the solid/liquid interface, which deteriorates the quality of the product obtained. Under these conditions, the pulled material presents poor properties with very high defect densities, in particular dislocations, bubbles, color centers (white or black), disorientations, mosaics, and displacements greater than 10° with respect to the pulling axis.

In this context, one of the objectives of the present invention is to provide a new type of crucible of a form adapted for growing large crystals, in particular growing monocrystals.

One of the aims of the invention is to provide a crucible with a structure such that it makes it possible to control crystallization by favoring growth axes of low Gibbs energy.

One of the aims of the invention is also to provide a crucible that can be implemented in a method that can be easily industrialized and that demonstrates improved production, in particular as compared to the prior art techniques that use external seeds to start crystallization.

The present invention has as an object a crucible, which is adapted for growing a large crystal from an adequate raw material, that includes a receptacle intended to accommodate the large crystal, wherein moreover, beneath the receptacle a vertical succession of at least two containers is located, with each container being connected to the container directly above by a restriction zone, and the uppermost container being connected by a restriction zone to the receptacle.

In an advantageous way, the crucible according to the invention presents one or more of the following characteristics (when one characteristic does not exclude another):
the bottom of the receptacle converges towards the restriction zone that connects the receptacle to the uppermost container, which is located below said receptacle,
the successive restriction zones are aligned vertically,
the central axis of each restriction zone coincides with the central axis of each container and with the central axis of the receptacle,
the successive containers are identical and the successive restriction zones are identical,
each container and each restriction zone that connects said container to the container or receptacle located directly above has a constant internal transverse cross-section, and the ratio between the internal transverse cross-section of the container and the internal transverse cross-section of the restriction zone is in the range between 2 and 50,
each restriction zone presents a constant internal transverse cross-section in the shape of disc,
the diameter of the internal transverse cross-section of each restriction zone is in the range between 200 μm and 1 mm,
each restriction zone presents a length in the range between 500 μm and 2 mm,
the crucible is comprised of graphite and presents advantageously a permeability in the range between 0.1 and 6 cm²/s, with an average porosity below 15% and an average pore diameter smaller than 10 μm,
the crucible is made of platinum or iridium.

According to another of its aspects, the present invention has an aim to provide a method that makes it possible to obtain crystals of good quality, by virtue of controlling the orientation of crystallization.

Thus, as well, the invention concerns a method for growing large crystals, starting with an adequate raw material, and using a crucible, as defined above, that makes it possible to control crystallization by favoring axes of low Gibbs energy.

In an advantageous way, the method according to the invention presents one or several of the following features (when one feature does not exclude another):
the method comprises the following successive steps:
   a) preparing a crucible, according to the invention, that is loaded with a raw material selected according to the crystal whose growth is desired, and placing said crucible in a vertical furnace,
   b) subjecting at least the raw material located in the lower container to a temperature sufficient to cause the raw material to melt,
   c) starting crystallization in the lower container by creating a crystallization front and moving this crystallization front vertically towards the top of the crucible according to a pulling rate such that the front passes through the successive containers and restriction zones until obtaining the crystallization of the desired large crystal in the receptacle.
the pulling rate is in the range between 1 and 4 mm/h,
the method is implemented for growing a large cubic monocrystal presenting a favored orientation, in particular, the orientation (111),
the method uses a graphite crucible according to the invention for growing a halide monocrystal of a periodic table group 1a or group 2a element, in particular of a fluoride chosen among: BaF₂, YF₃, LaF₃, EuF₃, TbF₃, SmF₃, PrF₃, CeF₃, or preferably CaF₂, or NaCl, with the pressure inside the furnace advantageously in the range between 1.3×10⁻¹ and 1.4×10⁻⁴ Pa, the method makes use of a crucible, according to the invention, made of iridium or platinum, for growing an oxide monocrystal chosen among Y₃Al₅O₁₂ and Gd₃Ga₅O₁₂.

The invention will be better understood by referring to the description presented below and the referenced illustrations attached hereto.

FIG. 1 presents a crucible of the prior art that is placed in a vertical furnace of the type used in the Bridgman technique.

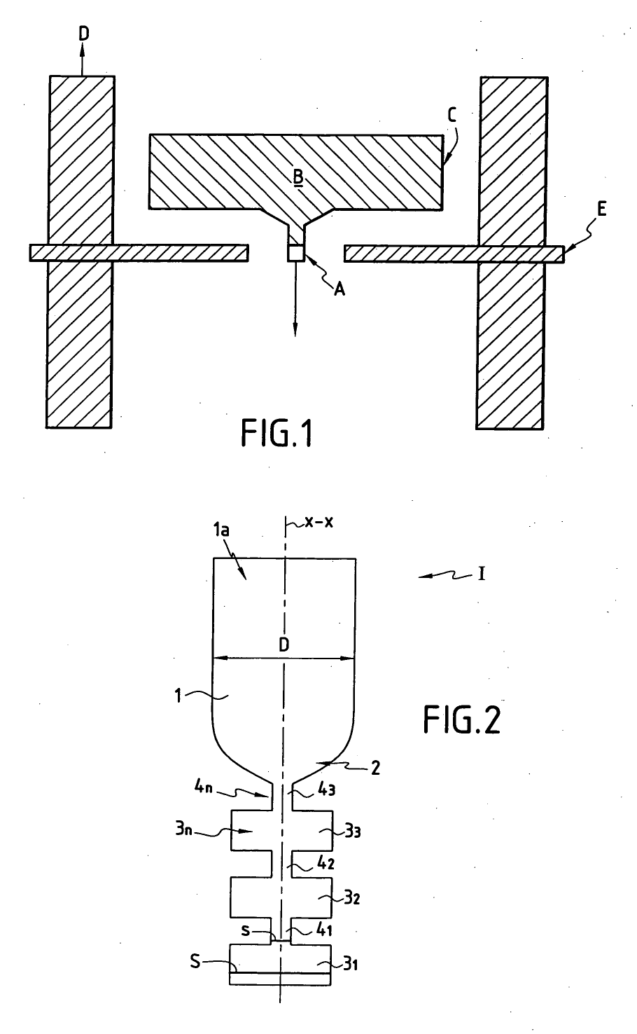

FIG. 2 is a cross-sectional diagram of a crucible that conforms to the invention.

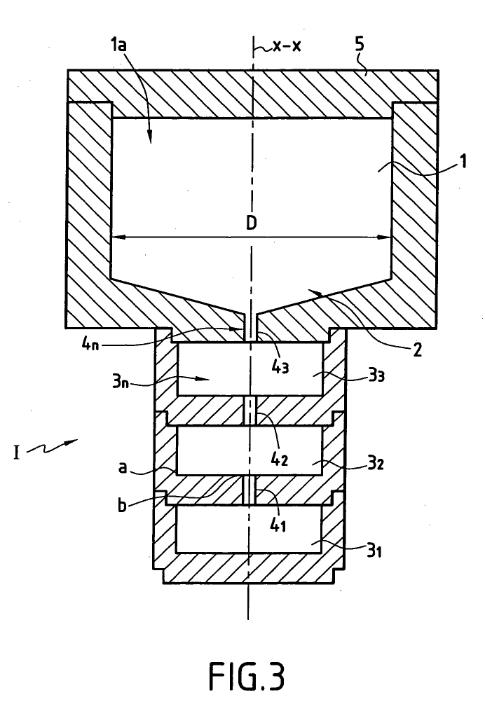

FIG. 3 is a cross-sectional diagram of another crucible that conforms to the invention.

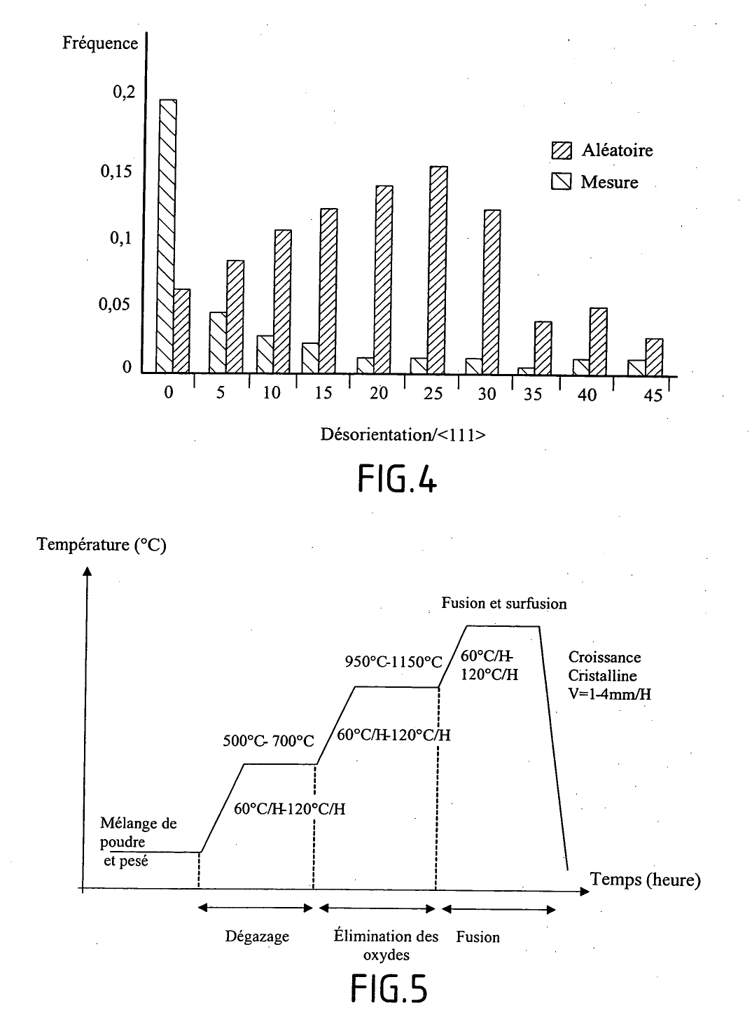

FIG. 4 shows the distribution of the measured orientations of a series of cubic crystals, obtained according to the method of the invention, whose favored growth axis is the axis (111).

FIG. 5 presents a temperature profile that can be used for growing CaF₂ according to the method of the invention.

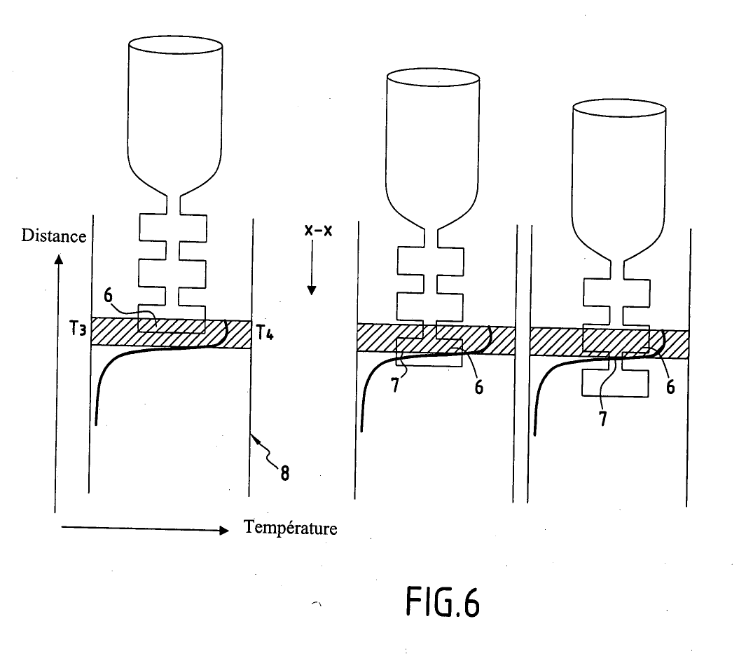

FIG. 6 illustrates some of the steps in one embodiment of the method according to the invention.

The invention provides a method of oriented crystalline growth by virtue of the use of a crucible of a specific form, without having to resort to an oriented external seed. The design of the crucible according to the invention makes it possible to generate growth along the growth axes that correspond to the Gibbs energy minima (V. E Puchin, A. V Puchina, M. Huisinga and M. Reiching J. Phys. Condens Matter 13 (2001) 2081).

The crucible I according to the invention is represented schematically in a longitudinal cross-section as seen in FIG. 2. The crucible I comprises a receptacle 1 in which the large crystal will be crystallized. This receptacle 1 is connected, at its base 2, to a series of at least two containers 3₁ to 3ₙ. The number of containers n is preferably in the range between 2 and 6, and is more preferably equal to 3 as in the examples illustrated in FIG. 2 and FIG. 3.

The various containers 3₁ to 3ₙ are continuously interconnected in order that the interiors of two successive containers are linked. Thus, during the implementation of the growth process, the crystallization front moves and passes from one container to another. The container 3ₙ located directly beneath the receptacle 1 is named the upper or last container. The lowest container 3₁ is named the lower or first container. The interior of the upper container 3ₙ (3₃ in the examples) is connected to the inside of receptacle 1, which is located directly above said upper container. The connection of the various elements of the crucible (the connection between two successive containers, the connection between upper container 3ₙ and receptacle 1) is made by the restriction zones 4₁ to 4ₙ. By restriction zones 4₁, 4₂, 4₃, . . . , it is meant a passage zone, a communication channel, notably, whose internal transverse cross-section s is smaller than the internal transverse cross-section S of containers 3₁, 3₂, 3₃, . . . . The restriction zone dimensions are determinant: they must present a length and a transverse cross-section adapted to ensure the propagation and conservation of the seeds of low Gibbs energy generated in situ, indeed to contribute to the elimination of the seeds of high Gibbs energy. In an advantageous way, the diameter of the internal transverse cross-section of each restriction zone 4₁, 4₂, 4₃, . . . , 4ₙ is in the range between 200 μm and 2 mm. Preferably, these restriction zones 4₁, 4₂, 4₃, . . . , 4ₙ are in the range between 500 μm and 1 mm in length.

In fact, the connections between the various elements of the crucible are made such that the upper part of an element is connected to the lower part of the succeeding element, in order that the interior of an element is linked with the interior of the element located directly above. In the examples presented in FIG. 2 and FIG. 3, the bottom of each container 3₂ to 3ₙ has an opening, and only the lower container 3₁ has a solid bottom.

Preferably, each container 3 and each restriction zone 4 that connects said container to the container or receptacle located directly above has a constant internal transverse cross-section, and the ratio of the internal transverse cross-section of said container on the internal transverse cross-section of the restriction zone located directly above is in the range between 2 and 50. In addition, the successive restriction zones 4₁, 4₂, 4₃, . . . , 4ₙ are aligned vertically in the illustrated examples, and, in an advantageous way, the central axis of each restriction zone 4₁, 4₂, 4₃, . . . , 4ₙ coincides with the central axis of each container 3₁, 3₂, 3₃, . . . , 3ₙ and with the central axis of receptacle 1, referred to as axis x-x. This axis x-x is parallel to the translation axis of the crucible and the vertical axis of the furnace. This axis can also be an axis of symmetry for the crucible in the case where all the elements of said crucible present a circular cross-section. In an equally preferred way, containers 3₁ to 3ₙ are all identical and restriction zones 4₁ to 4ₙ are all identical as well.

According to a preferred embodiment of the invention, as is illustrated in FIG. 2 and FIG. 3, the bottom of each container is perpendicular to the central axis x-x. Moreover, in an advantageous way, the junction a between the bottom and the peripheral wall of the interior of each container 3₁, 3₂, 3₃, . . . , 3ₙ forms an angle, preferably a right angle. Similarly, each restriction zone extends from the bottom of the container with which it ensures a connection according to an angular junction b.

The size of the receptacle 1 determines the size of the large crystal which is desired to be obtained. This receptacle 1 advantageously presents an internal volume that is much greater than that of containers 3₁ to 3ₙ, with a transverse cross-section equal to, or preferably larger than, said containers. Although a more or less parallelepipedic shape cannot be excluded, the principal part of the receptacle 1 advantageously presents a cylindrical shape. Consequently, the diameter D of this cylinder corresponds to the diameter of the crystal to be obtained, with the thickness of the crystal being determined by the rate at which the receptacle 1 is filled by the starting material. The dimensions of the receptacle 1 are such that they make possible to obtain crystals of diameters in the range between one centimeter and one hundred centimeters. The principal part of receptacle 1, for example, will present a transverse cross-section that corresponds to a disc with a diameter of between 1 and 100 cm.

In an advantageous way, the bottom 2 of the receptacle 1 converges towards the restriction zone 4₃ (4ₙ) that connects said receptacle to the upper container 3₃ (3ₙ) located directly below said receptacle, in order to facilitate the flow of the melt. In addition, in the example illustrated in FIG. 3, the receptacle 1, which has an opening at its upper end 1a, is topped with a cover 5 that ensures that said receptacle can be closed.

It is understood that the size of the crucible 1 is related to the constraints imposed by the dimensions of the vertical furnace used, the cost of constructing a crucible of the desired size, factors related to engineering, and the nature of the desired crystal.

In an advantageous way, the various elements of the crucible can be disassembled in order to facilitate their cleaning, the loading of the crucible, and the recovery of the crystal once the growth process is complete. Nevertheless, a non-preferred embodiment of the present invention, one in which the components are cast in a single piece, is by no means excluded. As illustrated in FIG. 3, the various components of the crucible can be stacked. In the example illustrated in FIG. 3, the restriction zones 4₁ to 4ₙ are channels cut in the bottoms of the containers 4₂ to 4ₙ. The restriction zone 4ₙ is cut in the bottom of the receptacle 1. Thus, the restriction zone lengths correspond to the thicknesses of the materials of which said bottoms are comprised.

The choice of the material of which the crucible I is comprised depends on the nature of the crystal to be grown. The choice of material is important, in particular in order to prevent the melt that is intended to be crystallized from becoming wet, from reacting, and from attacking the crucible, and also in order to facilitate the removal of the formed crystal from the mold. Preferably, the all of various elements of the crucible are comprised of the same material. For oxide growth, the crucible is advantageously made of iridium or platinum, whereas for fluoride growth, the crucible is made of graphite, which is easy to cut and to machine. Moreover, graphite plays a part in the elimination of scavengers. In a preferred way, the graphite used has a permeability (defined by DIN standard 51935: 1993-08) in the range between 0.1 and 6 cm²/s, with an average porosity below 15% and an average pore diameter smaller than 10 μm. The morphology of the graphite used, which presents very low pore densities, makes it possible to ensure a homogeneous flow through the various sections of the crucible I, and permits said flow to spread and to occupy the successive containers 3₁ to 3ₙ in an identical way. Such permeability facilitates passage through the restriction zones 4₁ to 4ₙ, and thus from one container to another, and makes it possible to avoid secondary nucleations that can cause random orientations to appear.

FIG. 4 shows the distribution of the orientations measured in a series of CaF₂ crystals prepared using the crucible I illustrated in FIG. 3, and this distribution confirms the favored orientation along the axis (111). As an example, porous graphite with large grains makes it impossible to generate favored orientations because under these conditions crystalline growth is uncontrolled and the CaF₂ crystals obtained have polycrystalline morphology and can contain twenty or so grains, visible to the eye, with large grain boundaries. The grains obtained are oriented chaotically and do not correspond to the orientations (100), (110), or (111), and only approximately 2% of the results deviate from the (111) direction by an angle less than 10°.

The present invention also has as an aim a process of crystalline growth that implements the crucible defined above.

This method advantageously comprises the following successive steps:
a) preparing a crucible, according to the invention, that is loaded with a raw material selected according to the crystal whose growth is desired, and placing said crucible in a vertical furnace,
b) subjecting at least the raw material located in the lower container to a temperature sufficient to cause the raw material to melt,
c) starting crystallization in the lower container by creating a crystallization front and moving this crystallization front vertically towards the top of the crucible according to a pulling rate such that the front passes through the successive containers and restriction zones until obtaining the crystallization of the desired large crystal in the receptacle.

The raw material is loaded such that all the various parts of the crucible I (the containers 3₁ to 3ₙ, the restriction zones 4₁ to 4ₙ, and the receptacle 1) are filled.

The growth process is carried out in a completely closed system with no provision for visualizing the pulling operation. It is for this reason that the temperatures in the regions where superheating, nucleation, and solidification of the material to be crystallized is desired must be known and specified for the dimensions of the crucible chosen and the furnace used. In an advantageous way, as illustrated in FIG. 6, the material contained in the lower container 3₁ is first subjected to primary melting in order to obtain the molten zone 6. It is also possible that the molten zone 6 extends through all the material contained in the crucible. Melting is carried out at a temperature higher than the melting temperature of the material to be crystallized. However, the temperature should not be too high to obtain a crystal of satisfactory transparency. Advantageously, the temperature used to melt the material will be in the range between the melting temperature M of the material to be crystallized and M+50° C.

Of course, the molten zone is not generated abruptly; temperature is made to rise in stages. In particular, the temperature profile used for growing CaF₂ is illustrated in FIG. 5. In an advantageous way, the following stages are carried out:
a first heating to temperature T1, in the range between 500° C. and 700° C., with a rate of rise in temperature on the order of 60° C./h-120° C./h, in order to degas the raw material,
a second heating from temperature T1 to temperature T2, T2 being in the range between 950° C. and 1150° C., with a rate of rise in temperature on the order of 60° C./h-120° C./h, in order to eliminate oxide residues through the action of the scavenger,
a final heating to a sufficient temperature T3 to cause the material to melt and to slightly superheat, with a rate of rise in temperature on the order of 60° C./h-120° C./h, with stabilization at temperature T3 for a few hours, for example 6 hours, to achieve complete melting.

Whichever embodiment is chosen (melting all of the material present in the crucible at temperature T3 or melting only that portion present in the lower container), the all of the material present in the crucible is subjected to the first two stages at temperatures T1 and T2.

Crystallization front movement can be accomplished by moving the crucible vertically inside the furnace, or by moving the furnace. In the case of moving the crucible vertically, the crucible I is subjected to vertical translation from the top to the bottom of the furnace 8 according to the vertical axis x-x of the furnace. A region of the furnace to which temperature T4 is subjected corresponds to a region of stable crystallization. When the melt reaches this region of the furnace, crystallization in the form of nucleation occurs, thus creating a solid/liquid interface, which is also referred to as the crystallization front 7. The vertical movement, which is applied to the crucible I inside the furnace 8 at a pulling rate that is advantageously in the range between 1 and 4 mm/h, makes it possible to move the solid/liquid interface 7 in the direction opposite of the movement of the crucible as illustrated in FIG. 6, which shows various relative positions of the melting zone (temperature T3) and the crystallization zone (temperature T4) within the crucible I in the furnace 8, as a function of the translation rate.

The growth process can be compared to standard Bridgman growth using an oriented seed. The essential difference of the invention with respect to the prior art arises from the specific configuration of the crucible I that makes it possible to be freed from the use of an external seed; in fact, the seed is created in situ.

Of course, control of the temperature profile inside the furnace and in particular at the solid/liquid interface must be ensured and modulated in order to avoid the problem of molten zone vibrations that are likely to modify the geometry of the solid/liquid interface during the growth process. A perturbation of the interface can result in the change of the thermal profile for the first portion of crystallized material, a change that can induce microscopic and macroscopic degradation of the properties of the pulled material. For this reason, controlled monitoring of the temperature inside the furnace, both transversely and longitudinally with respect to the crucible, must be ensured during the growth process. In an advantageous way, a vertical furnace that presents a longitudinal temperature gradient is used. On the other hand, the furnace temperature measured transversely is homogeneous.

When the vertical translatory movement of the crucible commences, crystallization starts at the bottom of the lower container 3₁ and creates a crystallization front 7 in the form of a solid/liquid interface. The movement of this solid/liquid interface is achieved, in the described embodiment, by virtue of the pulling rate determined by the vertical translatory movement of the crucible. In the example illustrated in FIG. 6, the zone 6, which corresponds to the melt, moves to the top of the crucible as a result of the vertical translation of the crucible I inside the furnace. The passage of the crystallization front 7 through the first restriction zone 4₁ makes it possible to eliminate some grains that may have already been formed in container 3₁. Indeed, the passage through the restriction zone 4₁, because of said restriction zone's relatively small cross-section, makes it possible to minimize the ratios of longitudinal and transversal temperature gradients and all the convection phenomena that occur in containers with cross-sections that are larger than that of said restriction zone. This first passage makes it possible to favor low energy grains because of the diffusion of high energy grains in the walls of the restriction 4₁ and the elimination of secondary nucleations due to the properties of the material of which the crucible is constituted. Moreover, the passage through the first restriction zone 4₁ makes it possible for the planes of low energy to coalesce to the detriment of those of higher energy.

In particular, in the case of the crystalline growth of a cubic monocrystal of favored orientation (111), and in particular of CaF₂, the circular cross-section of the restriction zone 4₁ and the properties of graphite (very low pore density, very fine grain, and permeability in the range between 0.1 and 6 cm²/s) constitute a barrier for the spread of secondary orientations and ensure the continuity of the crystalline growth of the primary seed that due to its low energy had been initiated during crystallization. Thus, the restriction zone 4₁ allows the passage of one or more seeds that correspond to the lowest Gibbs energies, of the favored orientation if present, and makes it possible to eliminate the majority of the high energy grains. The passage through the first restriction zone 4₁ is a first stage in the elimination of high Gibbs energy seeds or grains and the generation of controlled growth propagation in the following container 3₂. In this first stage of the process, there is thus nucleation of one or more seeds, which correspond to the weakest surface migration energies, through the restriction zone and then growth in the succeeding container. Indeed, the passage of the crystallization front 7 into the zone 3₂ makes it possible to increase the size of the crystal as a result of the ratios of the cross-section and the existing volume between the first restriction zone 4₁ and the second container 3₂, all the while preserving the same crystals already formed in the restriction 4₁. However, a strong competition exists between a grain of low energy and grains with energies close to that of said low energy grain. The passage of the crystallization front 7 through the second restriction zone 4₂ is a second path that makes it possible to eliminate the grains of high Gibbs energies by the diffusion of said high energy grains in the walls of the restriction zone 4₂. The passage through the first two restriction zones 4₁ and 4₂ already makes it possible to eliminate the majority of the secondary grains that are likely to appear with unfavorable orientations.

The passage into the container 3₃ that succeeds the second restriction zone 4₂ is a second way to carry out the preceding procedure in order to initiate the favored orientation, and so on, up to receptacle 1. The passage through the last restriction zone 4₃, or possibly 4ₙ, is the last way that makes it possible to reorganize the structural configuration of the atomic plane (hkl) that corresponds to the lowest Gibbs energy and to the best crystalline growth conditions given the geometrical configuration of the crucible.

In the case of growing monocrystals such as CaF₂, one or more of the seeds generated in the lower container correspond to the fastest axis of growth, and the growth conditions are preserved at all times during the propagation of the seed(s) within crucible I. Thus, one or more seeds of low energy are generated, propagated in the direction of crystallization, and preserved during the translatory movement of crucible I. In the method according to the invention, any contact between the lower energy seeds and the melt, under such conditions as might cause the aforesaid seeds to melt and thus to lose their direction, is avoided.

In the example illustrated in FIG. 6, the movement of the crystallization front 7 is accompanied by the movement of the molten zone 6, given that in step b) of the method according to the invention only the raw material located in the lower container 3₁, or even at the bottom of the lower container 3₁, is made to melt. On the other hand, during stage b) of the method according to the invention all the raw material contained in the crucible is made to melt, and the movement of the crystallization front 7 of the molten zone 6 is then accompanied by a reduction in said molten zone 6.

The crucible I and the method according to the present invention are quite particularly interesting for growing monocrystals, and in particular cubic crystals, that present favored (111) orientations. Notably, the halides associated with the elements of group 1a and group 2a of the periodic table and, in particular, the fluorides of composition CaF₂, BaF₂, YF₃, LaF₃, EuF₃, TbF₃, SmF₃, PrF₃, CeF₃, or still the chloride NaCl. For fluoride growth, graphite crucibles such as described above are used. In addition, classically, growth inside the furnace is carried out in the absence of oxygen and under reduced pressure, in particular at a pressure in the range between 1.3×10⁻¹ and 1.4×10⁻⁴ Pa.

Additionally, a mixture of the desired fluoride, in the form of a polycrystalline powder for example, and a powder of a scavenger present in an appropriate quantity, for example in a proportion between 5 and 10% by weight of the charged powder as described in the techniques of the prior art, is used advantageously as the raw material. The raw material presents, preferably, a high purity with a percentage of alkaline earth elements lower than 1 ppm, a percentage of alkaline elements lower than 0.5 ppm, and an H₂O content lower than 100 ppm. The charged polycrystalline powder has, advantageously, an average particle diameter of less than 20 μm and a density greater than 1.

The crucible I and the method according to the invention are also perfectly adapted to the growth of a cubic oxide for which the axis (111) is the favored orientation, such as Y₃Al₅O₁₂ and Gd₃Ga₅O₁₂. For oxide growth, the crucibles used are comprised of iridium or platinum and the atmosphere within the furnace can contain oxygen.

Nevertheless, the invention is also of interest for the preparation of polycrystals comprised of a reduced number of various large grains. In this case, it is possible to recover oriented crystals that follow specific directions from these polycrystals. The crystal of desired orientation is then cut directly at a known angle with respect to a crystal component of the polycrystal obtained.

### EXAMPLES

### Example 1

A graphite crucible, such as that presented in FIG. 3, is filled with a mixture of powder containing 95% CaF₂ by weight and 5% PbF₂ by weight. The powder used presents a water concentration on the order of 70 ppm. This water is present on the surface and can be easily eliminated starting at 100° C. We have noticed that it is essential to use a clean powder that does not contain H₂O molecules inside the CaF₂ structure. The presence of water causes the crystal to be contaminated by oxygen. The process of growth by pulling comprises four phases. The first phase is the heating of the lower container with the raw material under a high vacuum on the order of 1.33×10⁻³ Pa up to a temperature higher than the CaF₂ melting point (1,500° C.). The second phase is the maintaining of the liquid at this temperature for a sufficient period of time. The third phase is crystalline growth by the vertical movement of the crucible at a rate of approximately 2 mm/h to reach the cooling zone; the rate must be controlled automatically in order to avoid any fluctuation in the ratios of the transverse and longitudinal thermal gradients in the region of the molten zone. The fourth phase consists of the retrieving of the crucible after the cooling of the furnace at ambient temperature. The material obtained is easily removed from the crucible; it is monocrystalline and is oriented following the direction (111). The crystals obtained are free of cracks and bubbles and do not contain mosaics. The monocrystal obtained presents a transmission greater than 99% at 193 nm after optical polishing.

### Example 2

BaF₂ crystals are pulled using the same crucible design as described above. The growth process is the same as described in example 1. The liquid is maintained at a temperature on the order of 1,350° C. since the melting point of BaF₂ is lower than that of CaF₂. The pulling rate is on the order of 3 mm/h. The crystal is withdrawn from the crucible. The crystal presents a (111) orientation for the most part, in spite of some small grains which are disorientated with respect to each other.

1. A crucible (I) adapted for growing a large crystal, starting with an adequate raw material, comprising a receptacle (1) intended to accommodate the large crystal, wherein moreover, directly beneath the receptacle (1), a vertical succession of at least two containers (3₁, 3₂, 3₃, 3ₙ), with each container being connected by a restriction zone (4₁, 4₂, 4₃, 4ₙ) to the succeeding container located directly above, and the upper container (3₃, 3ₙ) being connected by a restriction zone (4₃, 4ₙ) to the receptacle (1).

2. A crucible (I) according to claim 1, wherein the bottom (2) of the receptacle (1) converges towards the restriction zone (4₃, 4ₙ) that connects said receptacle to the upper container (3₃, 3ₙ) located directly below said restriction zone.

3. A crucible (I) according to claim 1, wherein the successive restriction zones (4₁, 4₂, 4₃, 4ₙ) are aligned vertically.

4. A crucible (I) according to one claim 1, wherein the central axis of each restriction zone (4₁, 4₂, 4₃, 4ₙ) coincides with the central axis of each container (3₁, 3₂, 3₃, 3ₙ) and with the central axis of the receptacle.

5. A crucible (I) according to claim 1, wherein the successive containers (3₁, 3₂, 3₃, 3ₙ) are identical and wherein the successive restriction zones (4₁, 4₂, 4₃, 4ₙ) are identical as well.

6. A crucible (I) according to claim 1, wherein each container (3₁, 3₂, 3₃, 3ₙ) and each restriction zone (4₁, 4₂, 4₃, 4ₙ) that connects said container to the container or the receptacle located directly above has a constant internal transverse cross-section and the ratio between the internal transverse cross-section of the container and the internal transverse cross-section of the restriction zone is in the range between 2 and 50.

7. A crucible (I) according to claim 1, wherein each restriction zone (4₁, 4₂, 4₃, 4ₙ) presents a constant internal transverse cross-section in the shape of a disc.

8. A crucible (I) according to claim 7, wherein the diameter of the internal transverse cross-section of each restriction zone (4₁, 4₂, 4₃, 4ₙ) is in the range between 200 μm and 1 mm.

9. A crucible (I) according to claim 1, wherein each restriction zone (4₁, 4₂, 4₃, 4ₙ) presents a length in the range between 500 μm and 2 mm.

10. A crucible (I) according to claim 1, wherein said crucible is comprised of graphite.

11. A crucible (I) according to claim 10, wherein said crucible presents a permeability in the range between 0.1 and 6 cm²/s, with an average porosity lower than 15% and an average pore diameter smaller than 10 μm.

12. A crucible (I) according to claim 1, wherein said crucible is comprised of platinum or iridium.

13. In a method for growing a large crystal, starting with an adequate raw material, that makes it possible to control crystallization by favoring the axes of low Gibbs energy, the method using a crucible, the improvement comprising using the crucible (I) according to claim 1.

14. A method according to claim 13 wherein said method comprises the following steps:
a) loading the crucible (I) with a raw material selected according to the crystal whose growth is desired, and placing said crucible in a vertical furnace (8),
b) subjecting at least the raw material located in the lower container (3₁) to a temperature T3 sufficient to cause the raw material to melt,
c) starting crystallization in the lower container (3₁) by creating a crystallization front (7) and moving this crystallization front (7) vertically towards the top of the crucible (I) according to a pulling rate such that said crystallization front passes through the successive containers (3₁, 3₂, 3₃, 3ₙ) and the restriction zones (4₁, 4₂, 4₃, 4ₙ) until the crystallization of the desired large crystal in the receptacle (1) is obtained.

15. A method according to claim 14, wherein in step b) all the material contained in the crucible is subjected to a temperature T3 sufficient to cause said material to melt.

16. A method according to claim 14, wherein in step b) only the raw material located at the bottom of the lower container (3₁) is subjected to a temperature T3 sufficient to cause said raw material to melt.

17. A method according to claim 14, wherein the pulling rate is in the range between 1 and 4 mm/h.

18. A method according to claim 13, wherein said method is implemented for growing a large cubic monocrystal that presents a favored orientation.

19. A method according to claim 13, wherein the favored orientation is the orientation (111).

20. A method according to claim 13, wherein said method makes use of the crucible comprised of graphite or presenting a permeability in the range between 0.1 and 6 cm²/s, with an average porosity lower than 15% and an average pore diameter smaller than 10 μm for growing a halide monocrystal of an element from periodic table group 1a or group 2a.

21. A method according to claim 20, wherein the monocrystal is a fluoride chosen among: BaF₂, YF₃, LaF₃, EuF₃, TbF₃, SmF₃, PrF₃, CeF₃, or preferably CaF₂, or NaCl.

22. A method according to claim 20, wherein the pressure within the furnace is in the range between 1.3×10⁻¹ and 1.4×10⁻⁴ Pa.

23. A method according to claim 18, implemented for growing a CaF₂ monocrystal, wherein step b) comprises the following stages:
a first heating to temperature T1, in the range between 500° C. and 700° C., with a rate of rise in temperature on the order of 60° C./h-120° C./h, in order to degas the raw material,
a second heating from temperature T1 to temperature T2, T2 being in the range between 950° C and 1150° C., with a rate of rise in temperature on the order of 60° C./h-120° C./h, in order to eliminate oxide residues through the action of the scavenger,
a final heating to a sufficient temperature T3 to cause the material to melt and to slightly superheat, with a rate of rise in temperature on the order of 60° C./h-120° C./h, with stabilization at temperature T3 for a few hours to achieve complete melting.

24. A method according to claim 13, wherein said method uses the crucible (I) comprised of platinum or iridium for growing an oxide monocrystal chosen among Y₃Al₅O₁₂ or Gd₃Ga₅O₁₂.
